(19) United States
(12) Patent Application Publication
(10) Pub. No.: US 2023/0199363 A1
(43) Pub. Date: Jun. 22, 2023

(54) AUDIO PLAYBACK DEVICE

(71) Applicant: Shenzhen Uniwins Technology Co., Ltd, Shenzhen (CN)

(72) Inventors: Zhiyi Jiang, Shenzhen (CN); Meiyang Su, Shenzhen (CN)

(21) Appl. No.: 17/843,969

(22) Filed: Jun. 18, 2022

(30) Foreign Application Priority Data
Dec. 20, 2021 (CN) 202123207168.4

(51) Int. Cl. H04R 1/10; H02J 7/00; H05K 7/14

(52) U.S. Cl. CPC H04R 1/1016; H04R 1/1025; H04R 1/1075; H04R 1/1041; H02J 7/0044; H05K 7/1427; H04R 2420/07

(57) ABSTRACT

An audio playback device includes an audio playback apparatus and a charging storage box that satisfies placement of the audio playback apparatus, the audio playback apparatus includes a piece of connecting soft rubber, a sound nozzle fixedly connected to a side end portion of the connecting soft rubber, a speaker fixedly mounted inside the sound nozzle, a circuit component housing fixedly mounted at another side end portion of the connecting soft rubber, and a piece of memory metal cooperatively installed in the connecting soft rubber. The present device adopts ear clip type wearing, one end of the sound nozzle is inserted into the ear, the circuit component housing is placed behind the ear, since the soft rubber has a certain elasticity and with the unique shape of the sound nozzle, the audio playback apparatus can be firmly clamped on the ear.

### CROSS REFERENCE TO RELATED APPLICATIONS

The present application claims the benefit of Chinese Patent Application No. 202123207168.4 filed on Dec. 20, 2021, the contents of which are incorporated herein by reference in their entirety.

### TECHNICAL FIELD

The present disclosure relates to the technical field of audio playback equipment, in particular to an audio playback device.

### BACKGROUND TECHNOLOGY

At present, with the rapid development of the electronic industry, audio playback apparatuses have gradually evolved from large and bulky devices such as CD players, VCD players, DVD players, etc. to MP3 players, MP4 players, MP5 players, and smart phones and computers with audio functions, etc. With the development of technology, the current smart devices with audio functions will be used together with suitable wireless playback devices.

The current wireless audio playback apparatuses are generally ear-mounted or head-mounted. The ear-mounted type is easy to fall off during vigorous exercise or shaking of the head, while the head-mounted audio playback apparatus is bulky and inconvenient to carry. The ear-mounted or head-mounted audio playback apparatus easily makes a user fatigue after being worn for a long time, resulting in poor overall effect of usage. In order to solve the above problems, an audio playback device is proposed.

### SUMMARY OF THE DISCLOSURE

The purpose of the present disclosure is to provide an audio playback device in order to solve the above-mentioned problems.

The technical scheme adopted by the present disclosure is as follows: an audio playback device includes an audio playback apparatus and a charging storage box that satisfies placement of the audio playback apparatus, the audio playback apparatus including a piece of connecting soft rubber, a sound nozzle fixedly connected to a side end portion of the connecting soft rubber, a speaker fixedly mounted inside the sound nozzle, a circuit component housing fixedly mounted at another side end portion of the connecting soft rubber, the circuit component housing having an upper housing and a lower housing that are snap-fitted and held together, a piece of memory metal cooperatively installed in the connecting soft rubber, the connecting soft rubber as a whole being U-shaped, a position-limiting head integrally formed on the two side end portions of the connecting soft rubber, a position-limiting groove provided on the sound nozzle and the circuit component housing for cooperatively mounting with the position-limiting head, a storage battery mounted inside the circuit component housing, wherein the audio playback apparatus is inserted and fitted in a storage cavity inside the charging storage box.

In a preferred embodiment, a mirror display screen is provided on an outer side of the charging storage box, and a PCB mainboard is fixedly mounted on an upper side of the storage battery in an interior of the circuit component housing.

In a preferred embodiment, a Bluetooth component is welded on the PCB mainboard, the PCB mainboard is electrically connected to the speaker and the storage battery, and a soft rubber sleeve is mounted on an outer side of the sound nozzle.

In a preferred embodiment, a charging port is provided at one end of the circuit component housing, and a charging plug is provided on the storage cavity for cooperative connection with the charging port, and a signal light is provided on the circuit component housing.

In a preferred embodiment, the sound nozzle as a whole is in a shape of an end of a bottle mouth, and a cushion pad is adhered in the storage cavity.

In a preferred embodiment, a power display component is provided on the mirror display screen, and a second storage battery is provided inside the charging storage box.

In summary, due to the adoption of the above-mentioned technical solutions, the beneficial effects of the present device are:

1. In the present device, when in use, one end of the sound nozzle on the audio playback device is inserted into the ear, and the circuit component housing is placed behind the ear, and through the cooperation of the connecting soft rubber between the sound nozzle and the circuit component housing, the audio playback device can be fixedly clamped on the ear, it is more comfortable to wear, and it will not drop even during vigorous exercise, thereby ensuring the overall effect of wearing.

2. In the present device, by means of the characteristics of the overall shape, the audio playback device can also be used as a hand pressure relief toy, the good restoring capacity of the memory metal further improves its playfulness, and the memory metal can also avoid damage of the wires inside the soft rubber after repeated use, thereby improving the overall product life.

3. In the present device, during usage, when the audio playback device is put into or taken out from the storage box, the mirror display screen on the upper end of the storage box will light up and display the power supply status and the power level of the left and right audio playback devices. When the display screen is not in use, the screen body is a mirror, which can be convenient for users to put their clothes in order or some other operations, making the entire device more intelligent and novel.

### DESCRIPTION OF DRAWINGS

FIG. 1 is a schematic perspective view of the overall structure of the audio playback device of the present disclosure;

FIG. 2 is a schematic exploded view of the overall structure of the audio playback device of the present disclosure;

FIG. 3 is a schematic perspective view of the structure of the charging storage box of the present disclosure; and

FIG. 4 is a schematic view of the structure of the charging storage box of the present disclosure after it is opened.

Symbols in the figures: 1—audio playback apparatus, 11—upper housing, 12—PCB mainboard, 13—storage battery, 14—lower housing, 15—speaker, 16—sound nozzle, 17—connecting soft rubber, 18—memory metal, 2—charging storage box, 3—mirror display screen, 4—storage cavity, 5—charging plug.

### DETAILED DESCRIPTION OF EMBODIMENTS

In order to make the purpose, technical solutions and advantages of the present disclosure more clearly understood, the present disclosure will be further described in detail below with reference to the accompanying drawings and embodiments. It should be understood that the specific embodiments described herein are only used to explain the present disclosure, and are not used to limit the present disclosure.

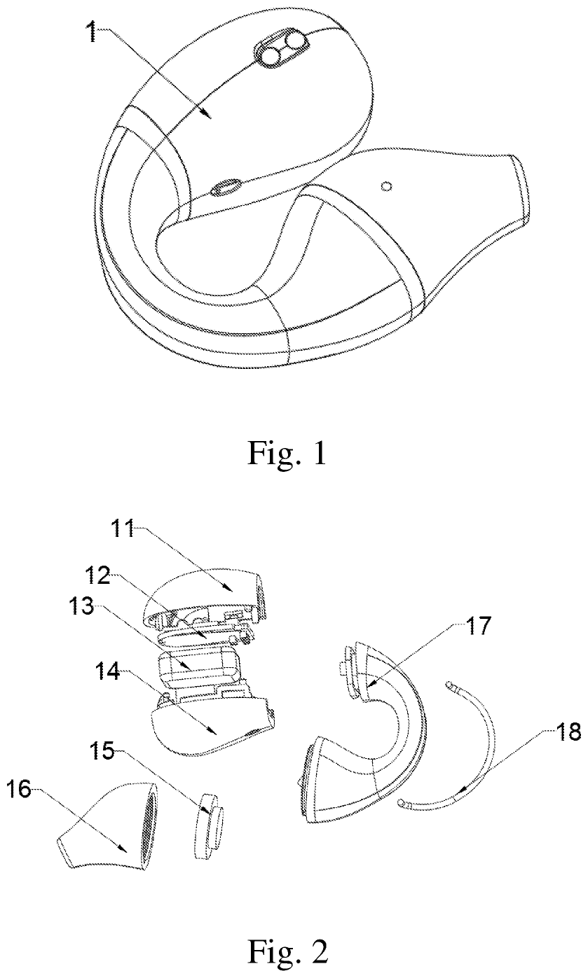

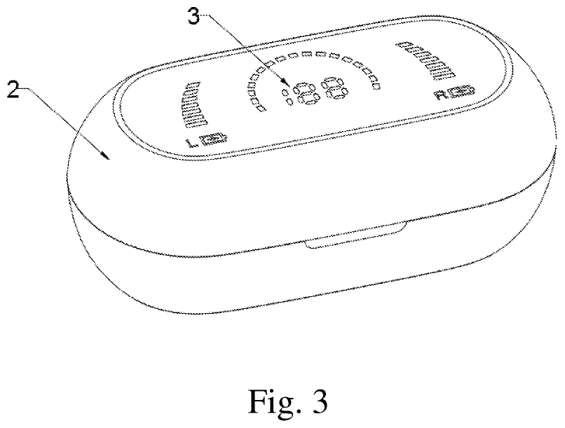

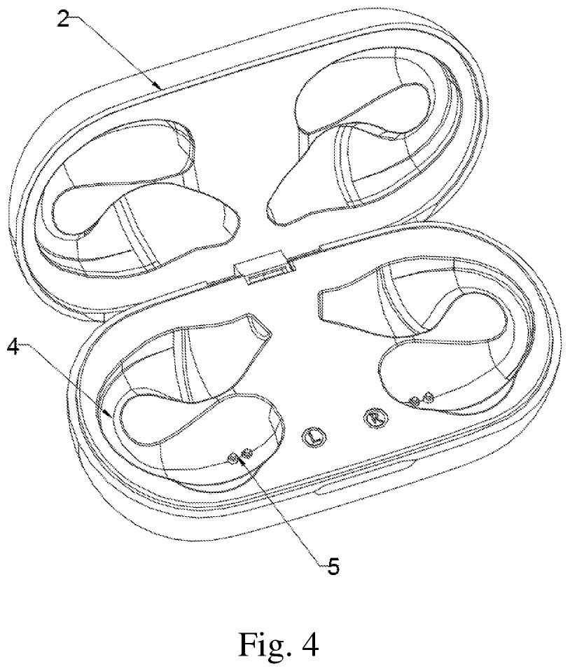

Referring to FIGS. 1-4, an audio playback device may include an audio playback apparatus 1 and a charging storage box 2 that satisfies placement of the audio playback apparatus 1. The audio playback apparatus 1 may include a piece of connecting soft rubber 17, a sound nozzle 16 fixedly connected to a side end portion of the connecting soft rubber 17, a speaker 15 fixedly mounted inside the sound nozzle 16, and a circuit component housing fixedly mounted on another side end portion of the connecting soft rubber 17. When usage is required, the audio playback apparatus 1 for the left and right ears is taken out, the end of the sound nozzle 16 of the audio playback apparatus 1 is inserted in the ear, and then the circuit component housing is placed behind the ear, and this completes the placement of the audio playback apparatus 1, which as a whole is an ear-mounting type. It is more comfortable to wear and will not drop even during vigorous exercise, and the overall wearing effect is ensured. The circuit component housing includes an upper housing 11 and a lower housing 14 that can be snap-fitted and held together, a piece of memory metal 18 may be cooperatively installed in the connecting soft rubber 17, the memory metal 18 has the advantage of high formability and strong restoring capacity, therefore during usage of the audio playback apparatus, the connecting soft rubber 17 can be held in a certain curvature, and it can also prevent the wires inside the soft rubber from being damaged after repeated use, a storage battery 13 may be mounted inside the circuit component housing, the storage battery 13 can provide power supply to the entire audio playback apparatus 1, the audio playback apparatus 1 may be inserted and fitted in a storage cavity 4 inside the charging storage box 2, a mirror display screen 3 may be provided on an outer side of the charging storage box 2, when the display screen is not in use, the screen body is a mirror, which can facilitate organizing of clothes and other operations by a user, a PCB mainboard 12 may be fixedly mounted on an upper side of the storage battery 13 in an interior of the circuit component housing, the operation of the entire device can be controlled by the PCB mainboard 12.

It should be noted that a Bluetooth component may be welded on the PCB mainboard 12, so that wireless signal transmission can be realized through the installation of the Bluetooth component, the PCB mainboard 12 can be electrically connected to the speaker 15 and the storage battery 13, a soft rubber sleeve may be installed on an outer side of the sound nozzle 16.

It should be noted that the connecting soft rubber 17 as a whole may be U-shaped, by means of the characteristics of the overall shape, the audio playback apparatus can also be used as a hand pressure relief toy, the high formability and strong restoring capacity of the memory metal further improves its playfulness, and the entire device may be in the shape of an ear clip, which increases the firm wearing effect, the two side end portions of the connecting soft rubber 17 may be integrally formed with a position-limiting head, a position-limiting groove may be provided on the sound nozzle 16 and the circuit component housing for cooperatively mounting with the position-limiting head.

It should be noted that a charging port may be provided at one end of the circuit component housing, a charging plug 5 may be provided on the storage cavity 4 for cooperative connection with the charging port, the charging storage box 2 can be charged through connection to an external power source, and the audio playback apparatus 1 in the storage cavity 4 can be charged at the same time, a signal light may be provided on the circuit component housing, the current operation status of the audio playback apparatus 1 can be checked through the signal light.

It should be noted that the sound nozzle 16 as a whole may be in the shape of an end of a bottle mouth, so as to facilitate the plugging of the sound nozzle 16 in the ear, a cushion pad may be adhered in the storage cavity 4, when the audio playback apparatus 1 is stored in the storage cavity 4, the cushion pad can provide the effect of cushioning and protecting the audio playback apparatus 1.

It should be noted that a power display component may be provided on the mirror display screen 3, the mirror display screen will light up and display the power supply status and the power level of the left and right audio playback apparatuses, a second storage battery may be provided inside the charging storage box 2, the source of power can be provided to the entire charging storage box 2 by the second storage battery, and the audio playback apparatus 1 can be charged through the charging storage box 2.

Principle of operation: before usage of the present device, the charging storage box 2 can be charged by connection to an external power source, and the audio playback apparatus 1 in the storage cavity 4 can be charged at the same time, when usage is required, the audio playback apparatus 1 for the left and right ears is taken out, and one end of the sound nozzle 16 of the audio playback apparatus 1 is inserted in the ear (located between the antihelix and the tragus), and then the circuit component housing is placed behind the ear, and this completes the placement of the audio playback apparatus 1, the connecting soft rubber 17 between the sound nozzle of the audio playback apparatus 1 and the circuit component housing has a certain elasticity, and with the unique shape of the sound nozzle 16, the audio playback apparatus 1 can be fixedly clamped on the ear, the present device as a whole may be of an ear-mounting type. It is more comfortable to wear and will not drop even during vigorous exercise, and the overall wearing effect is ensured, a piece of memory metal 18 may be installed in the connecting soft rubber 17, the memory metal 18 has the advantage of high formability and strong restoring capacity, therefore, during usage of the audio playback apparatus, the connecting soft rubber 17 can be held in a certain curvature, and it can avoid damage of the wires inside the soft rubber after repeated use, and the overall usage life is ensured.

By means of the characteristics of the overall shape, the audio playback apparatus can also be used as a hand pressure relief toy, the good restoring capacity of the memory metal further improves its playfulness, when the audio playback apparatus is put into or taken out from the storage box, the mirror display screen on the upper end of the storage box will light up and display the power supply status and the power level of the left and right audio playback apparatuses, the light will turn off after 15-30 seconds, when the display screen is not in use, the screen body can be a mirror, which is convenient for users to organize their clothes, and hence the overall practicability can be substantially increased.

The above are only preferred embodiments of the present disclosure, and are not intended to limit the present disclosure. Any modification, equivalent replacement and improvement made within the spirit and principle of the present disclosure shall be included within the scope of protection of the present disclosure.

What is claimed is:

1. An audio playback device, comprising an audio playback apparatus and a charging storage box that satisfies placement of the audio playback apparatus, the audio playback apparatus comprising a piece of connecting soft rubber, a sound nozzle fixedly connected to a side end portion of the connecting soft rubber, a speaker fixedly mounted inside the sound nozzle, a circuit component housing fixedly mounted at another side end portion of the connecting soft rubber, the circuit component housing having an upper housing and a lower housing that are snap-fitted and held together, a piece of memory metal cooperatively installed in the connecting soft rubber, the connecting soft rubber as a whole being U-shaped, a position-limiting head integrally formed on the two side end portions of the connecting soft rubber, a position-limiting groove provided on the sound nozzle and the circuit component housing for cooperatively mounting with the position-limiting head, a storage battery mounted inside the circuit component housing, wherein the audio playback apparatus is inserted and fitted in a storage cavity inside the charging storage box.

2. The audio playback device according to claim 1, wherein a mirror display screen is provided on an outer side of the charging storage box, and a PCB mainboard is fixedly mounted on an upper side of the storage battery in an interior of the circuit component housing.

3. The audio playback device according to claim 2, wherein a Bluetooth component is welded on the PCB mainboard, the PCB mainboard is electrically connected to the speaker and the storage battery, and a soft rubber sleeve is mounted on an outer side of the sound nozzle.

4. The audio playback device according to claim 1, wherein a charging port is provided at one end of the circuit component housing, and a charging plug is provided on the storage cavity for cooperative connection with the charging port, and a signal light is provided on the circuit component housing.

5. The audio playback device according to claim 1, wherein the sound nozzle as a whole is in a shape of an end of a bottle mouth, and a cushion pad is adhered in the storage cavity.

6. The audio playback device according to claim 2, wherein a power display component is provided on the mirror display screen, and a second storage battery is provided inside the charging storage box.
